(19) United States
(12) Patent Application Publication
(10) Pub. No.: US 2009/0217940 A1
(43) Pub. Date: Sep. 3, 2009

(54) REMOVAL OF PARTICLE CONTAMINATION ON PATTERNED SILICON/SILICON DIOXIDE USING DENSE FLUID/CHEMICAL FORMULATIONS

(75) Inventors: Michael B. Korzenski, Danbury, CT (US); Chongying Xu, New Milford, CT (US); Thomas H. Baum, New Fairfield, CT (US)

Correspondence Address: MOORE & VAN ALLEN PLLC, P.O. BOX 13706, Research Triangle Park, NC, 27709, US

(73) Assignee: Advanced Technology Marterials, Inc., Danbury, CT (US)

(21) Appl. No.: 12/066,600

(22) PCT Filed: Sep. 11, 2006
(86) PCT No.: PCT/US06/35033

§ 371 Date: Sep. 5, 2008

(30) Foreign Application Priority Data
Sep. 12, 2005 (US) 11224214

(51) Int. Cl. B08B 3/08; B65D 69/00; H01L 21/306; C11D 7/28

(52) U.S. Cl. 134/2; 206/223; 134/3; 510/175

(57) ABSTRACT

A cleaning composition for cleaning particulate contamination from small dimensions on microelectronic device substrates. The cleaning composition contains dense CO₂ (preferably supercritical CO₂ (SCCO₂)), alcohol, fluoride source, anionic surfactant source, non-ionic surfactant source, and optionally, hydroxyl additive. The cleaning composition enables damage-free, residue-free cleaning of substrates having particulate contamination on Si/SiO₂ substrates.

### FIELD OF THE INVENTION

The present invention relates to dense carbon dioxide-based compositions useful in microelectronic device manufacturing for the removal of particle contamination from patterned silicon/silicon dioxide substrates having such particle contamination thereon, and to methods of using such compositions for removal of particle contamination from microelectronic device substrates.

### DESCRIPTION OF THE RELATED ART

In the field of microelectronic device manufacturing, various methods are in use for cleaning wafers to remove particle contamination. These methods include ultrasonics, high pressure jet scrubbing, excimer laser ablation, and carbon dioxide snow-jet techniques, to name a few.

The use of air to blow away particles from microelectronic device substrates has been extensively investigated in recent years, as well as the dynamics of liquid jets for cleaning.

All of the methods developed to date have associated deficiencies.

More generally, the problems attendant with the removal of contaminant particles from microelectronic device substrates include the fact that surface contamination may be organic and/or inorganic in character, thereby complicating the cleaning process from the perspective of selecting compatible cleaning agents. In addition, not all surfaces to be cleaned are smooth and may possess varying degrees of roughness due to previous etching and/or deposition processes, thereby complicating the cleaning procedure. Still further, there exist several forces of adhesion, such as Van der Waals force of attraction, electrostatic interactions, gravity and chemical interactions, which impact the removal of contaminant particles. Accordingly, flow characteristics, chemistry and physical aspects are all involved, and complicate the removal of particulate contamination.

There is therefore a continuing need in the field for improved cleaning technology, since removal of particle contaminants from wafer surfaces is critical to ensure proper operation of the microelectronic device that is the ultimate product of the microelectronic device manufacturing process, and to avoid interference or deficiency in relation to subsequent process steps in the manufacturing process.

### SUMMARY OF THE INVENTION

The present invention relates to dense carbon dioxide-based compositions useful for cleaning applications, preferably in microelectronic device manufacturing for the removal of contaminant particles from substrates having such particles thereon, and methods of using such compositions for removal of contaminant particles from microelectronic device substrates.

In one aspect, the invention relates to a particle contamination cleaning composition, comprising at least one alcohol, at least one fluoride source, at least one anionic surfactant, at least one non-ionic surfactant, and optionally, at least one hydroxyl additive, wherein said cleaning composition is suitable for removing particle contamination from a microelectronic device having said particle contamination thereon. Preferably, the particle contamination cleaning composition further includes at least one dense fluid.

In another aspect, the invention relates to a method of removing particle contamination from a microelectronic device substrate having same thereon, said method comprising contacting the particle contamination with a cleaning composition for sufficient time to at least partially remove said particle contamination from the microelectronic device, wherein the cleaning composition includes at least one alcohol, at least one fluoride source, at least one anionic surfactant, at least one non-ionic surfactant, and optionally, at least one hydroxyl additive.

In yet another aspect, the invention relates to a kit comprising, in one or more containers, cleaning composition reagents, wherein the cleaning composition comprises at least one alcohol, at least one fluoride source, at least one anionic surfactant, at least one non-ionic surfactant, and optionally, at least one hydroxyl additive, and wherein the kit is adapted to form a cleaning composition suitable for removing particle contamination from a microelectronic device having said particle contamination thereon.

Yet another aspect of the invention relates to improved microelectronic devices, and products incorporating same, made using the methods and/or compositions described herein.

Yet another aspect of the invention relates to methods of manufacturing an article comprising a microelectronic device, said method comprising contacting the microelectronic device with a dense fluid cleaning composition for sufficient time to at least partially remove particle contamination from the microelectronic device having said particle contamination thereon, and incorporating said microelectronic device into said article, wherein the dense fluid cleaning composition includes at least one dense fluid, preferably supercritical carbon dioxide (SCCO₂), at least one alcohol, at least one fluoride source, at least one anionic surfactant, at least one nonionic surfactant, and optionally, at least one hydroxyl additive.

Other aspects, features and embodiments of the invention will be more fully apparent from the ensuing disclosure and appended claims.

### BRIEF DESCRIPTION OF THE DRAWINGS

FIG. 1 is an optical micrograph of a wafer comprising a patterned silicon dioxide layer and silicon layer, showing contaminant particles of SiN thereon, subsequent to cleaning thereof with SCCO2/methanol solution.

FIG. 2 is an optical micrograph of a wafer of the type shown in FIG. 1, after cleaning with a cleaning composition containing SCCO2, methanol and ammonium fluoride and boric acid.

FIG. 3 is an optical micrograph of a wafer of the type shown in FIG. 1, after cleaning with a cleaning composition containing SCCO2, methanol and a fluorinated surfactant.

FIG. 4 is an optical micrograph of a wafer of the type shown in FIG. 1, after cleaning with a cleaning composition containing SCCO2, methanol, ammonium fluoride, boric acid and a fluorinated surfactant.

FIG. 5 is a graph of the efficiency of particle removal from a silicon surface as a function of the concentration of anionic surfactant and hydroxyl additive.

FIG. 6 is a graph of the efficiency of particle removal from a silicon surface as a function of the concentration of non-ionic surfactant and hydroxyl additive.

FIG. 7 is a graph of the efficiency of particle removal from a silicon oxide surface as a function of the concentration of anionic surfactant and hydroxyl additive.

FIG. 8 is a graph of the efficiency of particle removal from a silicon oxide surface as a function of the concentration of non-ionic surfactant and hydroxyl additive.

FIG. 9 illustrates schematically the proposed method of removal of silicon nitride particulate matter from the silicon oxide surface using both an anionic and non-ionic surfactants.

FIGS. 10A and 10C are optical micrographs of a patterned silicon/silicon oxide wafer having silicon nitride particulate matter thereon before cleaning.

FIGS. 10B and 10D are optical micrographs of the wafers of FIGS. 10A and 10C, respectively, following cleaning with an optimized cleaning composition of the present invention.

FIG. 11 is a graph of the efficiency of particle removal and etch rate of both silicon and silicon oxide surfaces as a function of temperature.

FIG. 12 is a graph of the efficiency of particle removal and etch rate of both silicon and silicon oxide surfaces as a function of pressure.

### DETAILED DESCRIPTION OF THE INVENTION, AND PREFERRED EMBODIMENTS THEREOF

The present invention is based on the discovery of a dense carbon dioxide-based cleaning composition that is highly efficacious for the removal of contaminant particles from products, preferably microelectronic device substrates on which same are present. The compositions and methods of the invention are effective for removal of particles, including particles of organic and/or inorganic composition, from silicon and silicon dioxide regions of both blanket and patterned wafers.

As used herein, “particle contamination” includes particulate matter generated during any step of the microelectronic device manufacturing process including, but not limited to, post-etch residue, post-ash residue and post-chemical mechanical polishing (CMP) residue, and can include such species as aluminum oxide, silicon oxide, copper, copper oxides, tungsten, tungsten oxides, silicon nitride, silicon oxynitride, silicon oxyfluoronitride, silicon carbide, other oxide and nitride based residues, and combinations thereof. As used herein, “post-CMP residue” corresponds to particles from the polishing slurry, carbon-rich particles, polishing pad particles, brush deloading particles, equipment materials of construction particles, copper, copper oxides, aluminum, aluminum oxides, and any other materials that are the by-products of the CMP process.

As used herein, “underlying silicon-containing” layer corresponds to microelectronic device layer(s) that include the particle contamination thereon including: silicon; silicon oxide, silicon nitride, including gate oxides (e.g., thermally or chemically grown SiO₂); silicon nitride; and low-k silicon-containing materials, such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass.

For ease of reference, “microelectronic device” corresponds to semiconductor substrates, flat panel displays, and microelectromechanical systems (MEMS), manufactured for use in microelectronic, integrated circuit, or computer chip applications. It is to be understood that the term “microelectronic device” is not meant to be limiting in any way and includes any substrate that will eventually become a microelectronic device or microelectronic assembly.

“Dense” fluid, as used herein, corresponds to a supercritical fluid or a subcritical fluid. The term “supercritical fluid” is used herein to denote a material which is under conditions of not lower than a critical temperature, T_{c}, and not less than a critical pressure, P_{c}, in a pressure-temperature diagram of an intended compound. The preferred supercritical fluid employed in the present invention is CO₂, which may be used alone or in an admixture with another additive such as Ar, NH₃, N₂, CH₄, C₂H₄, CHF₃, C₂H₆, n-C₃H₈, H₂O, N₂O and the like. The term “subcritical fluid” describes a solvent in the subcritical state, i.e., below the critical temperature and/or below the critical pressure associated with that particular solvent. Preferably, the subcritical fluid is a high pressure liquid of varying density. Reference to supercritical fluid or supercritical CO₂ herein is not meant to be limiting in any way.

“Post-etch residue,” as used herein, corresponds to material remaining following gas-phase plasma etching processes, e.g., BEOL dual damascene processing. The post-etch residue may be organic, organometallic, organosilicic, or inorganic in nature, for example, silicon-containing material, carbon-based organic material, and etch gas residue such as oxygen and fluorine.

“Post-ash residue,” as used herein, corresponds to material remaining following oxidative or reductive plasma ashing to remove hardened photoresist and/or bottom anti-reflective coating (BARC) materials. The post-ash residue may be organic, organometallic, organosilicic, or inorganic in nature.

As defined herein, “substantially over-etching” corresponds to greater than 10% removal, preferably greater than 5% removal, more preferably greater than 2% removal, and most preferably greater than 1% removal, of the adjacent underlying silicon-containing layer(s) following contact, according to the process of the present invention, of the cleaning composition of the invention with the microelectronic device having said underlying layers.

As used herein, “about” is intended to correspond to ±5% of the stated value.

As used herein, “suitability” for removing particle contamination from a microelectronic device having said particle contamination thereon corresponds to at least partial removal of said particle contamination from the microelectronic device. Preferably, at least 85% of the particle contamination is removed from the microelectronic device using the compositions of the invention, more preferably at least 90%, even more preferably at least 95%, and most preferably at least 99% of the particle contamination is removed.

Importantly, the dense fluid compositions of the present invention must possess good metal compatibility, e.g., a low etch rate on the interconnect metal and/or interconnector metal silicide material. Metals of interest include, but are not limited to, copper, tungsten, cobalt, aluminum, tantalum, titanium and ruthenium.

Dense carbon dioxide (SCCO₂) might at first glance be regarded as an attractive reagent for removal of particulate contaminants, since dense CO₂ has the characteristics of both a liquid and a gas. Like a gas, it diffuses rapidly, has low viscosity, near-zero surface tension, and penetrates easily into deep trenches and vias. Like a liquid, it has bulk flow capability as a “wash” medium.

Despite these ostensible advantages, however, dense CO₂ is non-polar. Accordingly, it will not solubilize many species, including inorganic salts and polar organic compounds that are present in many contaminant particles and that must be removed from the microelectronic device substrate for efficient cleaning. The non-polar character of dense CO₂ thus poses an impediment to its use for cleaning of wafer surfaces of contaminant particles.

The present invention overcomes the disadvantages associated with the non-polarity of dense CO₂ by appropriate formulation of cleaning compositions including dense CO₂ and other additives as hereinafter more fully described, and the accompanying discovery that removing contaminant particles from both blanket and patterned microelectronic devices with said cleaning composition is highly effective and does not substantially over-etch the underlying silicon-containing layer(s) and metallic interconnect materials.

Compositions of the invention may be embodied in a wide variety of specific formulations, as hereinafter more fully described.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed.

The present invention relates to a particle contamination cleaning concentrate including at least one alcohol, at least one fluoride source, at least one nonionic surfactant, optionally at least one anionic surfactant, and optionally at least one hydroxyl additive. More specifically, the present invention contemplates a particle contamination cleaning concentrate including at least one alcohol, at least one fluoride source, at least one anionic surfactant, at least one nonionic surfactant and, optionally, at least one hydroxyl additive, present in the following ranges, based on the total weight of the composition:

| component of | % by weight |
|---|---|
| alcohol(s) | about 0.01% to about 99.5% |
| fluoride source(s) | about 0.01% to about 20.0% |
| anionic surfactant(s) | about 0.01% to about 20.0% |
| nonionic surfactant(s) | about 0.01% to about 20.0% |
| optional hydroxyl additive(s) | 0% to about 10.0% |

The cleaning concentrate may be combined with at least one dense fluid to form a dense fluid particle contamination cleaning composition. For example, the dense fluid cleaning composition useful in cleaning particle contamination from a microelectronic device, wherein said dense fluid cleaning composition includes the cleaning concentrate and at least one dense fluid, preferably SCCO₂, may include the components present in the following ranges, based on the total weight of the composition:

| component of | % by weight |
|---|---|
| dense fluid | about 45.0% to about 99.9% |
| cleaning concentrate | about 0.1% to about 55.0% |

preferably,

| component of | % by weight |
|---|---|
| dense fluid | about 85.0% to about 99% |
| cleaning concentrate | about 1% to about 15.0% |

In the broad practice of the invention, the cleaning concentrate may comprise, consist of, or consist essentially of at least one alcohol, at least one fluoride source, at least one anionic surfactant, at least one nonionic surfactant and, optionally, at least one hydroxyl additive. In the broad practice of the invention, the dense fluid cleaning composition may comprise, consist of, or consist essentially of at least one dense fluid and the cleaning concentrate. In general, the specific proportions and amounts of alcohol(s), fluoride source(s), anionic surfactant(s), nonionic surfactant(s) and, optionally, hydroxyl additive(s), in relation to each other and the dense fluid(s) may be suitably varied to provide the desired removal action of the dense fluid cleaning composition for the particle contamination and/or processing equipment, as readily determinable within the skill of the art without undue effort.

The dense fluid composition of the invention has utility for cleaning particulate contamination from small dimensions on microelectronic device substrates without further attack on Si-containing regions of the wafer.

In the dense fluid composition, the fluoride source aids in the removal of silicon impurities that reside on the microelectronic device surface. The fluoride source may be of any suitable type, e.g., a fluorine-containing compound or other fluoro species. Illustrative fluoride source components include hydrogen fluoride (HF), triethylamine trihydrogen fluoride or other amine trihydrogen fluoride compound of the formula NR₃(HF)₃ wherein each R is the same as or different from one another and is selected from hydrogen and lower alkyl (C₁-C₈ straight-chained and/or branched alkyls, e.g., methyl, ethyl, propyl, butyl, pentyl, hexyl, heptyl, octyl), hydrogen fluoride-pyridine (pyr-BF), and alkyl ammonium fluorides of the formula R₄NF, wherein each R is the same as or different from one another and is selected from hydrogen and lower (C₁-C₈ straight-chained and/or branched alkyls, e.g., methyl, ethyl, propyl, butyl, pentyl, hexyl, heptyl, octyl), etc. Ammonium fluoride (NH₄F) is a presently preferred fluorine source in compositions of the invention, although any other suitable fluoro source component(s) may be employed with equal success. The concentration of the fluorine source in the dense fluid composition may be in a range of from about 0.01 wt. % to about 10 wt. %, more preferably about 0.01 wt. % to about 5 wt. %, based on the total weight of the composition. It is to be understood by one skilled in the art that the dense fluid composition may also include fluorinated surfactant(s), which provide additional fluoride in the composition.

The optional hydroxyl additive functions to protect the oxide wafer from etching by the fluoride source. Boric acid is a presently preferred hydroxyl additive, although other hydroxyl agents may also be advantageously employed for such purpose, e.g., 3-hydroxy-2-naphthoic acid, iminodiacetic acid, triethanolamine, and combinations thereof. Further, the hydroxyl additive may also be a fluoride source, e.g., 2-fluorophenol, etc. The concentration of the hydroxyl additive in the dense fluid composition, when present, may be in a range of from about 0.01 wt. % to about 5 wt. %, more preferably about 0.01 wt. % to about 1 wt. %, based on the total weight of the composition.

The alcohol used to form the dense fluid/alcohol solution as the solvent phase of the dense fluid cleaning composition may be of any suitable type. In one embodiment of the invention, such alcohol comprises a C₁-C₄ alcohol (i.e., methanol, ethanol, straight-chained or branched propanol, or straight-chained or branched butanol), or a mixture of two or more of such alcohol species.

In a preferred embodiment, the alcohol is methanol. The presence of the alcoholic co-solvent with the dense fluid serves to increase the solubility of the dense fluid composition for inorganic salts and polar organic compounds present in the particulate contamination. In general, the specific proportions and amounts of dense fluid and alcohol in relation to each other may be suitably varied to provide the desired solubilizing (solvating) action of the dense fluid/alcohol solution for the particulate contamination, as readily determinable within the skill of the art without undue effort. The concentration of the alcohol in the dense fluid composition may be in a range of from about 0.01 wt. % to about 20 wt. %, more preferably about 1 wt. % to about 15 wt. %, based on the total weight of the composition.

The non-ionic surfactants used in the dense fluid composition of the present invention may include fluoroalkyl surfactants, polyethylene glycols, polypropylene glycols, polyethylene or polypropylene glycol ethers, carboxylic acid salts, dodecylbenzenesulfonic acid or salts thereof, polyacrylate polymers, dinonylphenyl polyoxyethylene, silicone or modified silicone polymers, acetylenic diols or modified acetylenic diols, and alkylammonium or modified alkylammonium salts, as well as combinations comprising at least one of the foregoing surfactants. The non-ionic surfactants are preferably fluorinated. The concentration of the non-ionic surfactant in the dense fluid composition may be in a range of from about 0.01 wt. % to about 10 wt. %, more preferably about 0.01 wt. % to about 1 wt. %, based on the total weight of the composition.

Anionic surfactants contemplated herein include, but are not limited to, fluorosurfactants such as ZONYL® UR and ZONYL® FS-62 (DuPont Canada Inc., Mississauga, Ontario, Canada), sodium alkyl sulfates, ammonium alkyl sulfates, alkyl (C₁₀-C₁₈) carboxylic acid ammonium salts, sodium sulfosuccinates and esters thereof, e.g., dioctyl sodium sulfosuccinate, alkyl (C₁₀-C₁₈) sulfonic acid sodium salts, as well as combinations comprising at least one of the foregoing surfactants. The anionic surfactants are preferably fluorinated. The concentration of the anionic surfactant in the dense fluid composition may be in a range of from about 0.01 wt. % to about 10 wt. %, more preferably about 0.01 wt. % to about 1 wt. %, based on the total weight of the composition.

In general, the specific proportions and amounts of at least one alcohol, at least one fluoride source, at least one anionic surfactant, at least one nonionic surfactant and, optionally, at least one hydroxyl additive, in relation to each other and the at least one dense fluid may be suitably varied to provide the desired solubilizing action of the dense fluid cleaning composition for the particle contamination to be removed from the microelectronic device. Such specific proportions and amounts are readily determinable by simple experiment within the skill of the art without undue effort.

It is to be understood that the phrase “removing particle contamination from a microelectronic device” is not meant to be limiting in any way and includes the removal of particle contamination from any substrate that will eventually become a microelectronic device.

In one embodiment, the dense fluid cleaning composition of the invention includes dense CO₂, alcohol, ammonium fluoride, nonionic fluorinated surfactant, and boric acid.

In another embodiment, the dense fluid cleaning composition of the invention includes dense CO₂, alcohol, ammonium fluoride, nonionic fluorinated surfactant, anionic fluorinated surfactant, and boric acid.

Another embodiment of the invention relates to a dense fluid cleaning composition comprising at least one dense fluid, at least one alcohol, at least one fluorine source, at least one nonionic surfactant, at least one anionic surfactant, particle contamination, and optionally at least one hydroxyl additive, wherein said particle contamination preferably comprises an organic and/or inorganic residue. In a preferred embodiment, this aspect of the invention relates to a dense fluid cleaning composition comprising dense CO₂, alcohol, ammonium fluoride, nonionic fluorinated surfactant, anionic fluorinated surfactant, boric acid, and particle contamination. Importantly, the particle contamination may be dissolved and/or suspended in the dense fluid cleaning composition of the invention. Such particle contamination may include post-etch, post-ash and/or post-CMP residue materials. According to one embodiment the contaminants may include, but are not limited to, SiN, silicon oxynitride, silicon oxyfluoronitride, silicon carbide, and combinations thereof.

In another preferred embodiment, the invention relates to a dense fluid cleaning composition comprising at least one dense fluid, at least one alcohol, at least one fluorine source, at least one nonionic surfactant, at least one anionic surfactant, and at least one hydroxyl additive.

In a preferred dense fluid cleaning composition of such character, as particularly adapted to cleaning of Si/SiO₂ wafer surfaces, ammonium fluoride is present at a concentration of from about 0.01 to about 5.0 wt. %, and boric acid is present at a concentration of from about 0.01 to about 2.0 wt. %, based on the total weight of the dense fluid cleaning composition.

The cleaning compositions of the invention may optionally be formulated with additional components to further enhance the removal capability of the composition, or to otherwise improve the character of the composition. Accordingly, the dense fluid composition may be formulated with stabilizers, complexing agents, passivators, e.g., Cu passivating agents, etc.

The dense fluid cleaning compositions of the invention are easily formulated by addition of the alcohol(s), fluoride source(s), anionic surfactant(s), nonionic surfactant(s) and, optional hydroxyl additive(s), i.e., the concentrate, to a dense CO₂ solvent. The alcohol(s), fluoride source(s), anionic surfactant(s), nonionic surfactant(s) and, optional hydroxyl additive(s), i.e., the concentrate, may be readily formulated as single-package concentrate formulations or multi-part concentrate formulations that are mixed at the point of use. The individual parts of the multi-part formulation may be mixed at the manufacturer, at the tool or in a storage tank upstream of the tool. The concentrations of the single-package concentrate formulations or the individual parts of the multi-part concentrate formulation may be widely varied in specific multiples, i.e., more dilute or more concentrated, in the broad practice of the invention, and it will be appreciated that the cleaning concentrate, and hence the dense fluid cleaning compositions, of the invention can variously and alternatively comprise, consist or consist essentially of any combination of ingredients consistent with the disclosure herein.

Accordingly, another aspect of the invention relates to a kit including, in one or more containers, one or more components adapted to form the cleaning concentrates of the invention. Preferably, the kit includes, in one or more containers, at least one alcohol, at least one fluoride source, at least one anionic surfactant, at least one nonionic surfactant and, optionally, at least one hydroxyl additive for combining with the dense fluid at the fab. According to another embodiment, the kit includes, in one or more containers, at least one fluoride source, at least one anionic surfactant, at least one nonionic surfactant and, optionally, at least one hydroxyl additive for combining with the at least one alcohol and the dense fluid at the fab. These examples are not meant to limit said kit in any way. The containers of the kit should be chemically rated to store and dispense the component(s) contained therein. For example, the containers of the kit may be NOWPak® containers (Advanced Technology Materials, Inc., Danbury, Conn., USA).

The dense fluid cleaning compositions of the present invention are readily formulated by simple mixing of ingredients, e.g., in a mixing vessel or the cleaning vessel under gentle agitation. The cleaning vessel may also have internal agitation mechanism, i.e. stirring, megasonics, to aid in particle removal.

Once formulated, such dense fluid cleaning compositions are applied to the microelectronic device surface for contacting the particle contamination thereon, at suitable elevated pressures, e.g., in a pressurized contacting chamber to which the SCF-based composition is supplied at suitable volumetric rate and amount to effect the desired contacting operation, for at least partial removal of the particle contamination from the microelectronic device surface. The chamber may be a batch or single wafer chamber, for continuous, pulsed or static cleaning.

The removal efficiency of the dense fluid cleaning composition may be enhanced by use of elevated temperature and/or pressure conditions in the contacting of the particle contamination to be removed with the dense fluid cleaning composition.

The dense fluid cleaning composition can be employed to contact a substrate having particulate contamination thereon at a pressure in a range of from about 1000 to about 7500 psi for sufficient time to effect the desired removal of the particulate contamination from the substrate, e.g., for a contacting time in a range of from about 5 to about 30 minutes and a temperature of from about 35 to about 100° C., although greater or lesser contacting durations and temperatures may be advantageously employed in the broad practice of the present invention, where warranted.

The cleaning process in a particularly preferred embodiment includes sequential processing steps including dynamic flow of the dense fluid cleaning composition over the substrate having the particulate contamination thereon, followed by a static soak of the substrate in the dense fluid cleaning composition, with the respective dynamic flow and static soak steps being carried out alternatingly and repetitively, in a cycle of such alternating steps. A “dynamic” contacting mode involves continuous flow of the composition over the device surface, to maximize the mass transfer gradient and effect complete removal of the particle contamination from the surface. A “static soak” contacting mode involves contacting the device surface with a static volume of the composition, and maintaining contact therewith for a continued (soaking) period of time.

For example, the dynamic flow/static soak steps may be carried out for three successive cycles in the aforementioned illustrative embodiment of contacting time of 30 minutes, as including a sequence of 10 minutes dynamic flow, 10 minutes static soak, and 10 minutes dynamic flow.

It is to be appreciated by one skilled in the art that the contacting mode can be exclusively dynamic, exclusively static or any combination of dynamic and static steps needed to effectuate at least partial removal of the particle contamination from the microelectronic device surface.

Following the contacting of the dense fluid cleaning composition with the substrate bearing the particulate contamination, the substrate thereafter preferably is washed with copious amounts of a first washing solution, e.g., SCCO₂/alcohol solution (not containing any other components) such as a 20% methanol solution, in a first washing step, to remove any residual precipitated chemical additives from the substrate region in which removal of particulate contamination has been effected, and finally with copious amounts of pure SCCO₂, in a second washing step, to remove any residual alcohol co-solvent and/or precipitated chemical additives from the substrate region.

Yet another aspect of the invention relates to the improved microelectronic devices made according to the methods of the invention and to products containing such microelectronic devices.

A still further aspect of the invention relates to methods of manufacturing an article comprising a microelectronic device, said method comprising contacting the microelectronic device with a dense fluid cleaning composition for sufficient time to at least partially remove particle contamination from the microelectronic device having said particle contamination thereon, and incorporating said microelectronic device into said article, wherein the dense fluid cleaning composition includes at least one dense fluid, preferably supercritical carbon dioxide (SCCO₂), at least one alcohol, at least one fluoride source, at least one anionic surfactant, at least one nonionic surfactant, and optionally, at least one hydroxyl additive.

The features and advantages of the invention are more fully shown by the empirical efforts and results discussed below.

In one embodiment, substantial removal of SiN particles from an Si/SiO2 substrate was achieved using SCCO₂ compositions including an alcohol (15 wt %)/fluoride (0.55 wt %) concentrate at a temperature and pressure of 55° C. and 4000 psi, respectively, using a processing time of 30 minutes (10 minute dynamic flow, 10 minute static soak, 10 minute dynamic flow, followed by a three volume SCCO₂/methanol (20 wt %) rinse and pure three volume SCCO₂ rinse). As defined herein, “substantial removal” corresponds to at least 90% removal of particulate matter, preferably at least 95%, more preferably at least 98%, and most preferably at least 99% of the particulate matter is removed.

In another embodiment, substantial removal of SiN particles from an Si/SiO2 substrate was achieved using SCCO₂ compositions including an alcohol (6 wt %)/fluoride (0.80 wt %)/boric acid (0.23 wt %)/nonionic fluorosurfactant (0.31 wt %)/anionic fluorosurfactant (0.27 wt %) concentrate at a temperature and pressure of 70° C. and 3000 psi, respectively, using a processing time of 10 minutes (5 minute dynamic flow, 5 minute static soak, followed by a three volume SCCO₂/methanol (20 wt %) rinse and pure three volume SCCO₂ rinse).

### Example 1

The sample wafers examined in this study included silicon nitride particles residing on a patterned silicon dioxide layer and silicon layer. The samples were first processed using pure SCCO2 at 50° C. and 4400 psi, and although the velocity of the flowrate (10 mL/min) removed some of the particles, it was ineffective at completely removing all of the contaminate particles.

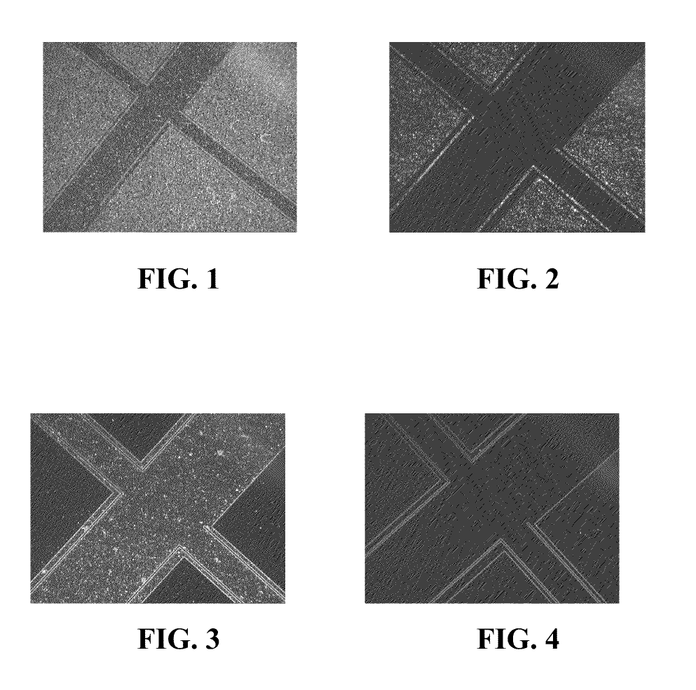

FIG. 1 is an optical microscope photograph of this wafer comprising a patterned silicon dioxide layer and silicon layer, showing contaminant particles of SiN thereon, subsequent to cleaning thereof with SCCO2/methanol solution.

Various chemical additives/surfactants then were added to the SCCO2/methanol solution and their particle removal efficiency was examined.

FIG. 2 shows the optical image of the wafer cleaned with a SCCO2/methanol/boric acid/NH₄F solution at 50° C. and clearly shows that the SiN particles are removed from the SiO₂ surface, however, this cleaning solution was not effective toward removing the particles from the silicon regions. The boric acid was used both to protect the SiO₂ surface from attack by the fluoride ions, as well as to hydrogen bond to the silicon oxide surface to assist in lift-off of the particles which are most likely held via Van der Waals forces. The fluoride source was used to aid in particle removal by chemically reacting with the SiN particles, thus aiding in their removal from the wafer surface. A covalent fluoride source, that does not generate HF upon exposure to moisture, is generally desired for particle removal from silicon surfaces.

FIG. 3 is an optical microscope photograph of a wafer of the type shown in FIG. 1, after cleaning with a cleaning composition containing SCCO2, methanol and a fluorinated surfactant. As can be seen from FIG. 3, the SCCO2/methanol/F-surfactant solution did not remove particles from the SiO₂ surface.

FIG. 4 is an optical microscope photograph of a wafer of the type shown in FIG. 1, after cleaning with a cleaning composition containing SCCO2, methanol, ammonium fluoride, boric acid and a fluorinated surfactant, showing that such composition successfully removed surface particles from the entire patterned wafer.

The above-described photographs thus evidence the efficacy of cleaning compositions in accordance with the invention, for removal of particulate contamination on wafer substrates.

It will be appreciated that specific contacting conditions for the cleaning compositions of the invention are readily determinable within the skill of the art, based on the disclosure herein, and that the specific proportions of ingredients and concentrations of ingredients in the cleaning compositions of the invention may be widely varied while achieving desired removal of the post etch residue from the substrate.

### Example 2

The sample wafers examined in this study included silicon or silicon oxide wafers having silicon nitride particle matter thereon. The processing conditions included temperature of 70° C., pressure around 3000 psi and a process time in the range of 2 to 30 minutes, preferably in the range of 5 to 10 minutes. The process flow used may be either a static soak or a dynamic flow. The cleaning composition included SCCO₂, about 5 wt. % to about 15 wt. % methanol, boric acid as the hydroxyl additive, about 0.8 wt. % ammonium fluoride as the etchant, non-ionic surfactant and anionic surfactant.

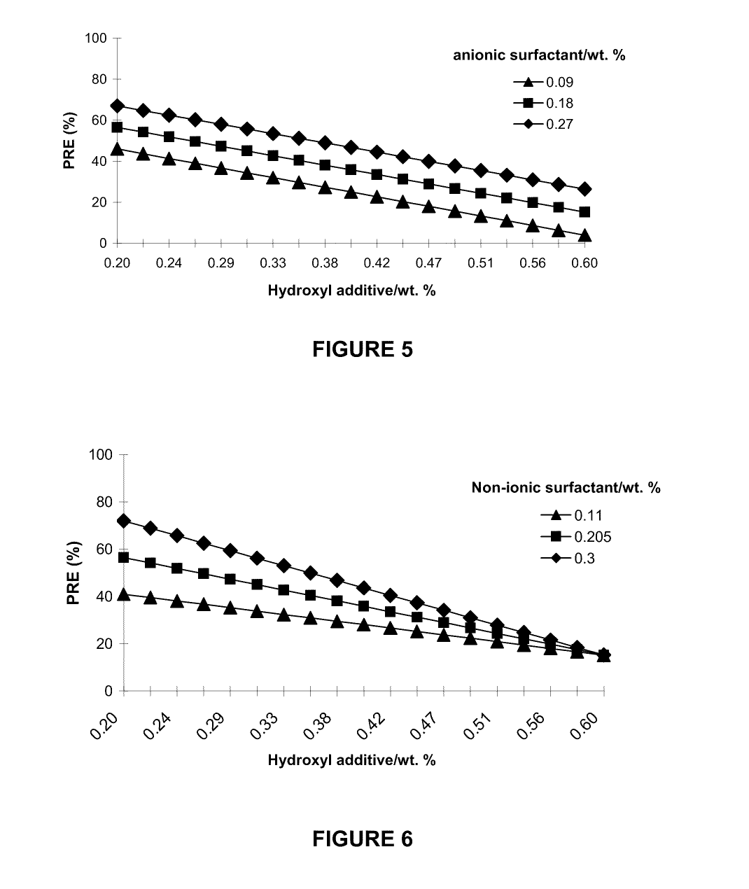

FIG. 5 illustrates the particle removal efficiency (PRE) for the removal of silicon nitride particles from a silicon surface using a cleaning composition including 0.205 wt. % non-ionic surfactant and varying concentrations of hydroxyl additive (0.20-0.60 wt. %) and anionic surfactant (0.09-0.27 wt. %). It can be seen that both the anionic surfactant and the hydroxyl additive have an effect on the PRE, whereby the lower the hydroxyl additive concentration and the higher the anionic surfactant concentration, the higher the PRE.

FIG. 6 illustrates the particle removal efficiency (PRE) for the removal of silicon nitride particles from a silicon surface using a cleaning composition including 0.18 wt. % anionic surfactant and varying concentrations of hydroxyl additive (0.20-0.60 wt. %) and non-ionic surfactant (0.11-0.30 wt. %). It can be seen that both the non-ionic surfactant and the hydroxyl additive have an effect on the PRE, whereby the lower the hydroxyl additive concentration and the higher the non-ionic surfactant concentration, the higher the PRE.

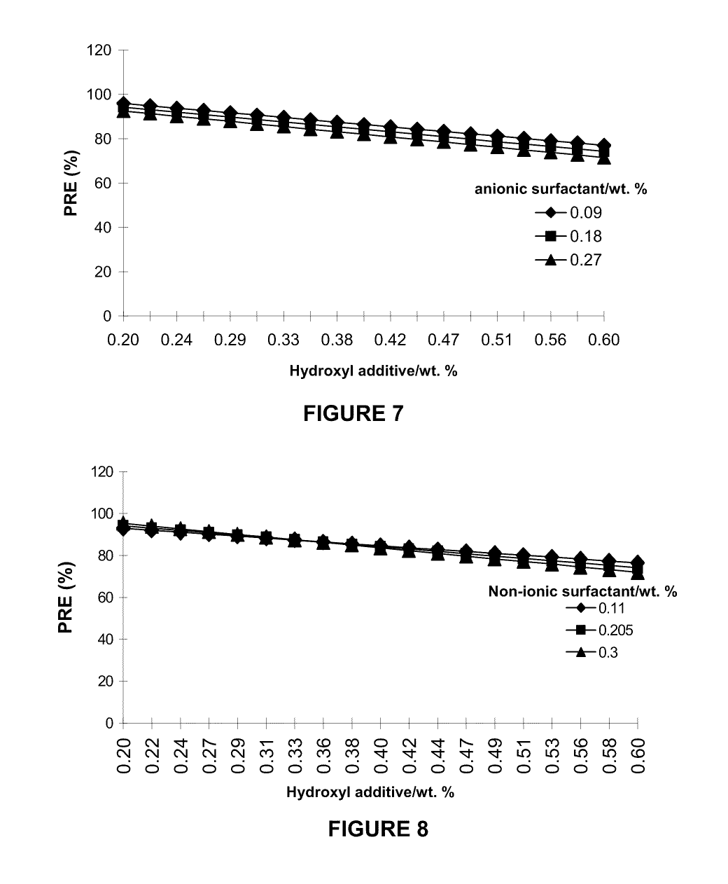

FIG. 7 illustrates the particle removal efficiency (PRE) for the removal of silicon nitride particles from a silicon oxide surface using a cleaning composition including 0.205 wt. % non-ionic surfactant and varying concentrations of hydroxyl additive (0.20-0.60 wt. %) and anionic surfactant (0.09-0.27 wt. %). It can be seen that both the anionic surfactant and the hydroxyl additive have an effect on the PRE, whereby the lower the hydroxyl additive concentration and the higher the anionic surfactant concentration, the higher the PRE.

FIG. 8 illustrates the particle removal efficiency (PRE) for the removal of silicon nitride particles from a silicon oxide surface using a cleaning composition including 0.18 wt. % anionic surfactant and varying concentrations of hydroxyl additive (0.20-0.60 wt. %) and non-ionic surfactant (0.11-0.30 wt. %). It can be seen that both the non-ionic surfactant and the hydroxyl additive have an effect on the PRE, whereby the lower the hydroxyl additive concentration and the higher the non-ionic surfactant concentration, the higher the PRE.

In one embodiment, when cleaning particulate matter from a surface including SiO₂ using a dense fluid composition of the invention, preferably the weight percent of hydroxyl additive≅weight percent of non-ionic surfactant≅weight percent of the anionic surfactant, based on the total weight of the composition. When cleaning particulate matter from a surface including Si using a dense fluid composition of the invention, preferably the weight percent of hydroxyl additive≅weight percent of non-ionic surfactant≅weight percent of the anionic surfactant, and more preferably, the weight percent of hydroxyl additive<weight percent of non-ionic surfactant≅weight percent of the anionic surfactant, based on the total weight of the composition.

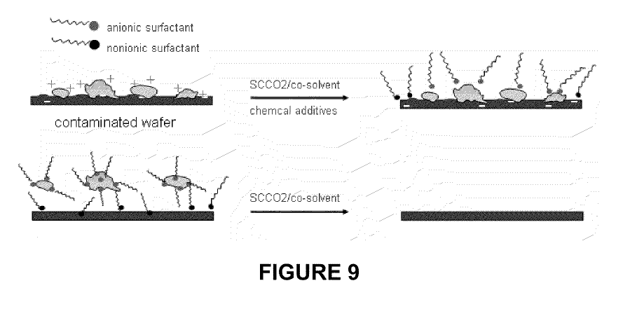

Importantly, the magnitude of PRE was greater when silicon nitride particles were removed from the SiO₂ surface, indicating that the surfactants interacted with the SiO₂ surface more than the Si surface, thus aiding in particle removal. Although not wishing to be bound by theory, this effect is thought to be the result of the more negative zeta potential of the SiO₂ surface relative to the more neutral (less negative) Si surface. When the fluoride source undercuts the SiO₂ layer, the anionic surfactant attaches to the silicon nitride particulate matter while the non-ionic surfactant attaches to the SiO₂ surface, probably via hydrogen bonding. The net result is particle removal by way of steric repulsion of the surfactant tails towards each other as illustrated schematically in FIG. 9. For the silicon surface, which is most likely hydrogen terminated, the non-ionic surfactant is less likely to attach to the surface due to repulsion between the two hydrogen atoms and as such, particle removal is more a function of the anionic surfactant attaching to the silicon nitride particles only.

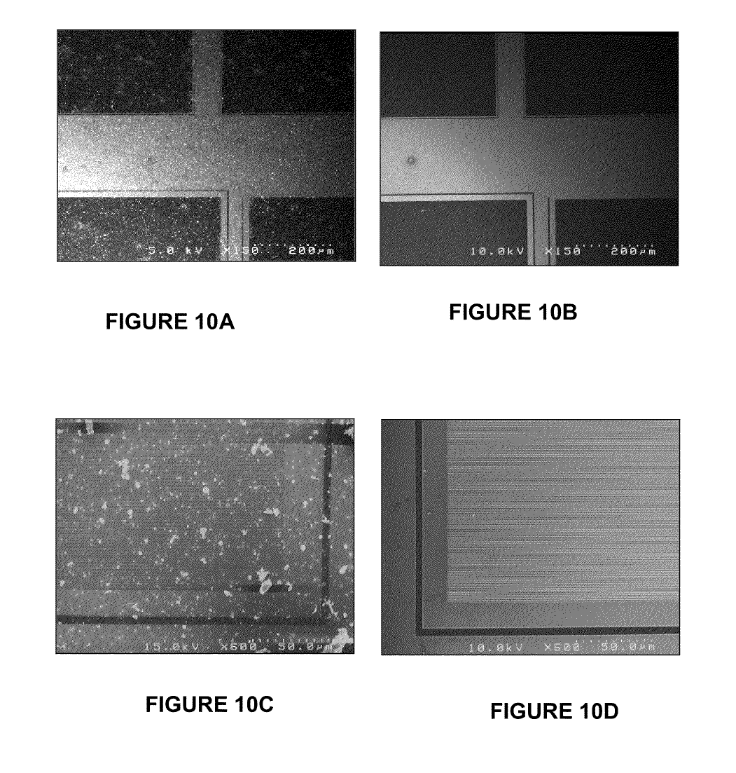

FIGS. 10A and 10C are optical micrographs of a patterned silicon/silicon dioxide wafer showing contaminant particles of SiN thereon, prior to cleaning with the optimized SCCO2 cleaning composition. FIGS. 10B and 10D are optical micrographs of the FIGS. 10A and 10C wafers, respectively, after cleaning with the optimized cleaning composition containing SCCO2, methanol, ammonium fluoride, boric acid, anionic surfactant, and non-ionic surfactant, showing that such composition successfully removed surface particles from the entire patterned wafer.

### Example 3

Using the optimized cleaning composition of Example 2, patterned silicon/silicon oxide wafers having silicon nitride particle matter thereon were cleaned to determine the effects of temperature and pressure on the PRE, keeping all other variables constant. The cleaning composition included SCCO₂, about 5 wt. % to about 15 wt. % methanol, a low concentration of boric acid as the hydroxyl additive, about 0.8 wt. % ammonium fluoride as the etchant, a high concentration of non-ionic surfactant and a high concentration of anionic surfactant.

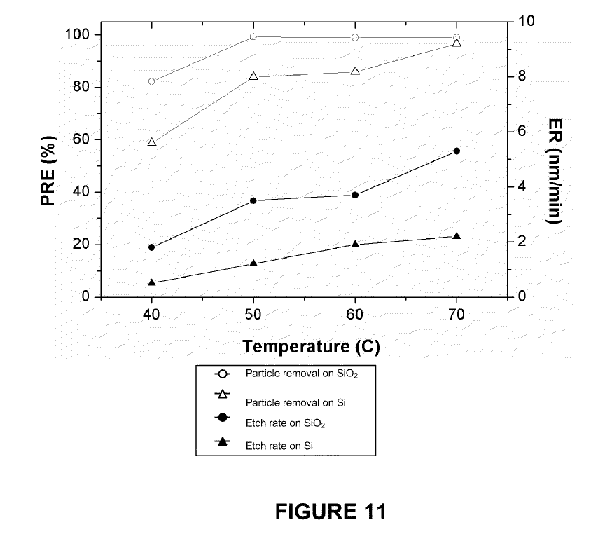

FIG. 11 illustrates the particle removal efficiency (PRE) for the removal of silicon nitride particles from the patterned silicon/silicon oxide surface, as well as the etch rate of the silicon/silicon oxide surface, using the SCCO₂ cleaning composition at a constant pressure of 2800 psi. It can be seen that as the temperature of the composition is increased, both the PRE and the etch rate of the silicon and silicon oxide surfaces increase.

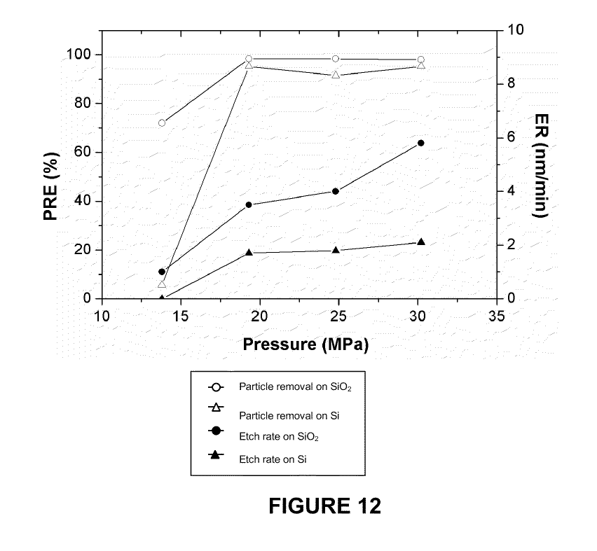

FIG. 12 illustrates the particle removal efficiency (PRE) for the removal of silicon nitride particles from the patterned silicon/silicon oxide surface, as well as the etch rate of the silicon/silicon oxide surface, using the SCCO₂ cleaning composition at a constant temperature of 70° C. It can be seen that as the pressure of the composition is increased, the PRE levels out at 19.3 MPa however, the etch rate of both the silicon and silicon oxide surfaces continues to increase.

Accordingly, while the invention has been described herein in reference to specific aspects, features and illustrative embodiments of the invention, it will be appreciated that the utility of the invention is not thus limited, but rather extends to and encompasses numerous other aspects, features and embodiments. Accordingly, the claims hereafter set forth are intended to be correspondingly broadly construed, as including all such aspects, features and embodiments, within their spirit and scope.

1. A particle contamination cleaning composition, comprising at least one alcohol, at least one fluoride source, at least one anionic surfactant, at least one non-ionic surfactant, and optionally, at least one hydroxyl additive, wherein said cleaning composition is suitable for removing particle contamination from a microelectronic device having said particle contamination thereon.

2. The composition of claim 1, wherein the at least one alcohol comprises C₁-C₄ alcohol, and wherein the at least one fluoride source comprises a fluoride-containing compound selected from the group consisting of: hydrogen fluoride (HF); amine trihydrogen fluoride compounds of the formula NR₃(HF)₃, wherein each R is the same as or different from one another and is selected from hydrogen and lower alkyl; hydrogen fluoride-pyridine (pyr-HF); and ammonium fluorides of the formula R₄NF, wherein each R is the same as or different from one another and is selected from hydrogen and lower alkyl.

3. The composition of claim 1, wherein the at least one alcohol comprises methanol.

4. The composition of claim 1, wherein the at least one fluoride source comprises ammonium fluoride (NH₄F).

5. The composition of claim 1, comprising the at least one hydroxyl additive.

6. The composition of claim 5, wherein the at least one hydroxyl additive comprises a species selected from the group consisting of boric acid and 2-fluorophenol.

7. The composition of claim 5, wherein the at least one hydroxyl additive is also a fluoride source.

8. The composition of claim 1, wherein the at least one anionic surfactant is fluorinated.

9. The composition of claim 1, wherein the at least one non-ionic surfactant is fluorinated.

10. The composition of claim 5, comprising ammonium fluoride, at least one fluorinated surfactant and boric acid.

11. The composition of claim 5, comprising ammonium fluoride, a fluorinated anionic surfactant, a fluorinated nonionic surfactant, and boric acid.

12. A dense fluid cleaning composition comprising at least one dense fluid and the cleaning composition of claim 1.

13. The dense fluid cleaning composition of claim 12, wherein the at least one dense fluid comprises supercritical carbon dioxide (SCCO₂).

14. The dense fluid composition of claim 12, wherein said at least one alcohol has a concentration in a range of from about 1 to about 20 wt. %, based on total weight of the composition.

15. The dense fluid composition of claim 12, wherein the at least one fluoride source has a concentration of from about 0.01 to about 2.0 wt. %, based on the total weight of the cleaning composition.

16. The composition of claim 1, wherein the microelectronic device comprises an article selected from the group consisting of semiconductor substrates, flat panel displays, and microelectromechanical systems (MEMS).

17. The composition of claim 1, wherein the microelectronic device comprises silicon and/or silicon dioxide.

18. The composition of claim 1, wherein the particle contamination comprises a species selected from the group consisting of aluminum oxide, silicon oxide, copper, copper oxides, tungsten, tungsten oxides, silicon nitride, silicon oxynitride, silicon oxyfluoronitride, silicon carbide, and combinations thereof.

19. A kit comprising, in one or more containers, cleaning composition reagents, wherein the cleaning composition comprises at least one alcohol, at least one fluoride source, at least one anionic surfactant, at least one non-ionic surfactant, and optionally, at least one hydroxyl additive, and wherein the kit is adapted to form a cleaning composition suitable for removing particle contamination from a microelectronic device having said particle contamination thereon.

20. A method of removing particle contamination from a microelectronic device substrate having same thereon, said method comprising contacting the particle contamination with a cleaning composition for sufficient time to at least partially remove said particle contamination from the microelectronic device, wherein the cleaning composition includes at least one alcohol, at least one fluoride source, at least one anionic surfactant, at least one non-ionic surfactant, and optionally, at least one hydroxyl additive.

21.-32. (canceled)
